(19) United States
(12) Patent Application Publication
(10) Pub. No.: US 2025/0358949 A1
(43) Pub. Date: Nov. 20, 2025

(54) STRUCTURAL DRIVE ASSEMBLY

(71) Applicant: International Business Machines Corporation, Armonk, NY (US)

(72) Inventors: Karl Stathakis, Rochester, MN (US); William James Anderl, Rochester, MN (US); Phillip V. Mann, Rochester, MN (US); Curtis Eugene Larsen, Eden Valley, MN (US); Kevin O'Connell, Mantorville, MN (US); Brandon R. Christenson, Kasson, MN (US)

(21) Appl. No.: 18/663,835

(22) Filed: May 14, 2024

(51) Int. Cl. H05K 7/14

(52) U.S. Cl. CPC H05K 7/1487

(57) ABSTRACT

A structural drive assembly is provided. The structural drive assemble includes a storage device and a carrier. The storage device has a first mounting feature on one side of the storage device and a second mounting feature on another side of the storage device. The carrier includes a top portion and a bottom portion. The top portion attaches to one side of the storage device using the first mounting feature. The bottom portion attaches to the other side of the storage device using the second mounting feature.

### BACKGROUND

The present invention relates to server chassis and more specifically, to the installation of storage devices in the server chassis.

A server chassis, also known as a server case or server enclosure, is a specialized housing that contains and protects the internal components of a server. It is designed to provide physical support, cooling, and access to the server's components while ensuring proper airflow and minimizing electromagnetic interference.

A server chassis requires structural support to provide stability, rigidity, and protection for the internal components of the server. This support is essential for ensuring that the server can withstand the stresses and vibrations associated with operation, transportation, and handling. Overall, the structural support in a server chassis is designed to ensure the reliable and safe operation of the server under various conditions, while also providing easy access to components for maintenance and upgrades.

### SUMMARY

Embodiments of the present disclosure are directed to a structural drive assembly. The structural drive assemble includes a storage device and a carrier. The storage device has a first mounting feature on one side of the storage device and a second mounting feature on another side of the storage device. The carrier includes a top portion and a bottom portion. The top portion attaches to one side of the storage device using the first mounting feature. The bottom portion attaches to the other side of the storage device using the second mounting feature.

Embodiments of the present disclosure are directed to a server system. The server system includes a server chassis that does not have structural bracing in the front. The server system also includes a structural drive assemble that includes a storage device and a carrier. The storage device has a first mounting feature on one side of the storage device and a second mounting feature on another side of the storage device. The carrier includes a top portion and a bottom portion. The top portion attaches to one side of the storage device using the first mounting feature. The bottom portion attaches to the other side of the storage device using the second mounting feature. The structural drive assembly is configured to anchor to the server chassis through an interface component of the server chassis and provide structural rigidity to the server chassis

### BRIEF DESCRIPTION OF THE DRAWINGS

FIG. 1 is a perspective view of a structural drive assembly according to an illustrative embodiment.

FIG. 2A is a rear view of the assembly including the carrier and storage device 110 together, according to embodiments.

FIG. 2B is a side view of the carrier and storage device together according to embodiments.

FIG. 2C is a front view of the carrier and storage device together, according to embodiments.

FIG. 3 is a side view of the assembly mounted or installed within a server chassis according to an illustrative embodiment.

FIG. 4A illustrates a front view of the two-part drive latch mechanism according to an illustrative embodiment.

FIG. 4B illustrates a front view of the two-part drive latch mechanism according to an illustrative embodiment.

FIG. 5 is a profile view illustrating an alternative embodiment of carrier with a T shaped flange according to an illustrative embodiment.

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to computing systems, more particular aspects relate to providing structural support for a server chassis from the storage devices contained within the server chassis. While the present disclosure is not necessarily limited to such applications, various aspects of the disclosure may be appreciated through a discussion of various examples using this context.

In a server, structural integrity is obtained in the frontal dive region of the server with the use of ribs/braces. Typically, these are interspersed between the various drives. This approach is particularly prevalent in 2U servers having twenty four (24) 2.5″ drives. In these situations, there is typically a brace adjacent to drives-8 and −16. However, using such braces causes two problems with airflow. The first is that each brace takes up approximately 1 mm of space by itself. As such, two braces would reduce the total width available for the drives by about 2-3 mm. Second, even if one were to assume that the braces had a zero thickness, the single channel between the two drives becomes two half width channels. As these channels are narrower they have a higher Reynolds number, which results in greater turbulence. This results in higher airflow impedance and less airflow. To combat this, the channels associated with the braces must be widened. This results in less pitch between the remaining drives.

Through these two effects, including two 1 mm-thick braces, results in the reduction of effective drive space by approximately 5 mm. This converts to approximately 0.2 mm per drive in a twenty-four drive configuration. In this situation, the drive region can contribute to 40-50% of total system pressure drop. While 0.2 mm of pitch reduction may seem trivial it can materially harm overall airflow in a space-constrained design with many drives.

To address this issue, the present disclosure presents a solution that uses the drives themselves as structural reinforcement for the front section of chassis while at the same time minimizing airflow blockage at the very front of the chassis.

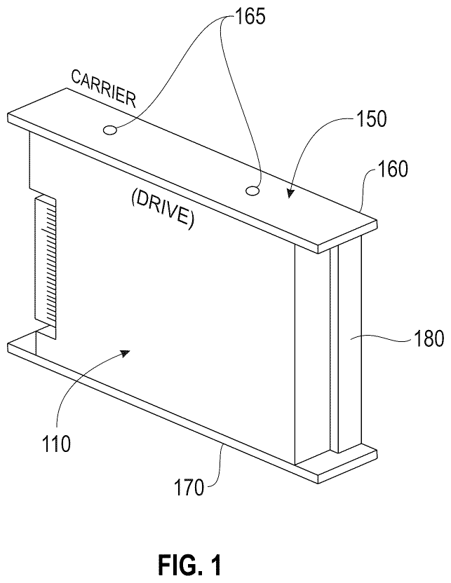

FIG. 1 is a perspective view of a structural solid state drive (SSD) assembly 100 according to embodiments of the present disclosure. The structural SSD assembly 100, or assembly 100 includes a storage device 110 and a carrier 150.

The storage device 110 is in one embodiment a solid state drive. However, the storage device 110 can be any other type of storage device 110 that is used within a server environment. The storage device 110 includes one or more mounting holes or brackets that permit the storage device 110 to be securely installed in a particular environment. Typical storage devices have two connection points on each side of the device for accepting screws 115 or pins to attach the storage device 110 in its intended installation. For purposes of this discussion, screws 115 will be considered as the connection means. Again, other connection means can be used if the storage device 110 is so designed, such as pins or latches.

The carrier 150 is provided in the assembly 100 to enable the necessary structural rigidity for the server chassis 300 that would have previously been provided by the braces in traditional systems. The carrier 150 includes a top portion 160 and a bottom portion 170. The top portion 160 is designed to connect to the top of the storage device 110, and the bottom portion 170 is designed to connect to the bottom of the storage device 110. The top and bottom portion 170s have holes 165 provided in them at locations that correspond to the mounting system on the storage device 110. When screws 115 or other connection means are used, the top and bottom portions 160, 170 of the carrier 150 are fixedly connected to the storage device 110. In some embodiments, the carrier 150 further includes at least one bracket 180, 190 connecting the top portion 160 and the bottom portion 170 together. These brackets can be aligned with either the front of the carrier 150 relative to the storage device 110 or the rear of the carrier 150 relative to the storage device 110. These brackets 180, 190 can provide additional structural rigidity for the carrier 150 and hence the server chassis 300.

The top portion 160 and the bottom portion 170 are sized such that they are the same size as the width as the storage device 110. So for a 2.5 inch drive the portions would be approximately 15 mm in width. While illustrated as having the same width as the storage device 110 it should be recognized that depending on the particular design and end environment, the width of the top portion 160 and the bottom portion 170 can be less than the width of the storage device 110. The width of the top portion 160 and the bottom portion 170 can be wider than the width of the storage device 110 as well. However, this comes at disadvantage in that the space between the storage devices may not be able to be fully optimized due to this extra width. The length of the top portion 160 and the bottom portion 170 is longer than the length of the drive to which they will be attached. This is to permit the carrier 150 to interface and connect with corresponding structure in the server chassis 300.

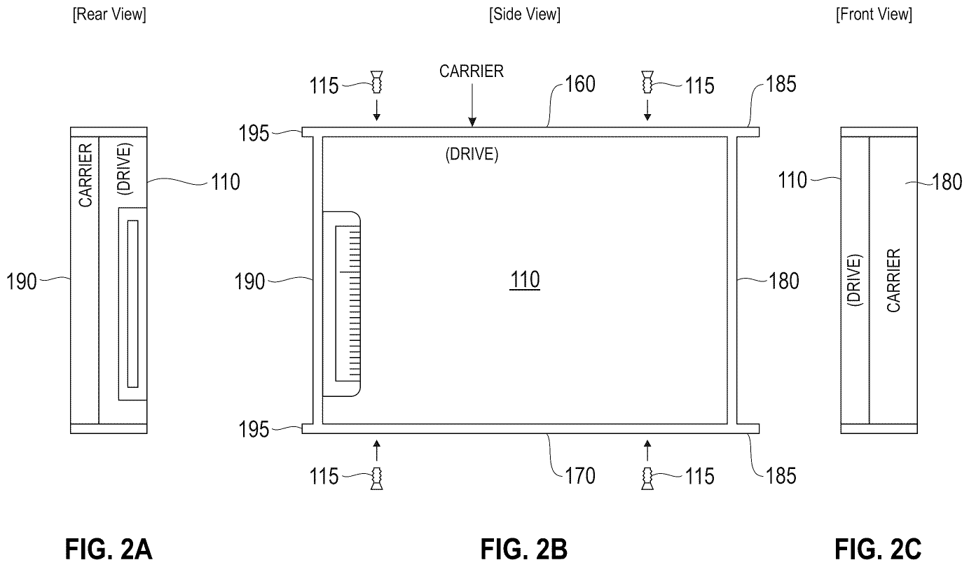

FIG. 2A is a rear view of the assembly 100 including the carrier 150 and storage device 110 together, according to embodiments. FIG. 2B is a side view of the carrier 150 and storage device 110 together according to embodiments. FIG. 2C is a front view of the carrier 150 and storage device 110 together, according to embodiments. The storage device 110 is aligned in a vertical direction such that it is on end within the carrier 150. On the top portion 160 and the bottom portion 170 of the carrier 150 are locations of the holes 165 where the screws 115 can be used to attach the storage device 110 to the carrier 150. A front bracket 180 and a rear bracket 190 are illustrated connecting the top portion 160 and the bottom portion 170 of the carrier 150 together. The front backet and the rear bracket 190 provide additional structural rigidity to the carrier 150. At the rear portion of the top and bottom portion 170s and near the rear bracket 190 are extensions 195 that allow the carrier 150 to interface with the server chassis 300. This interfacing will be discussed in greater detail later in this description. Further as illustrated in FIGS. 2A and 2C the front and rear brackets 180, 190 are narrower than the width of the corresponding storage device 110. This is provided to assist with accessing the storage device 110 and can also provide enhanced thermal properties. The top portion 160 and the bottom portion 170 are, again illustrated having the same width as the storage device 110.

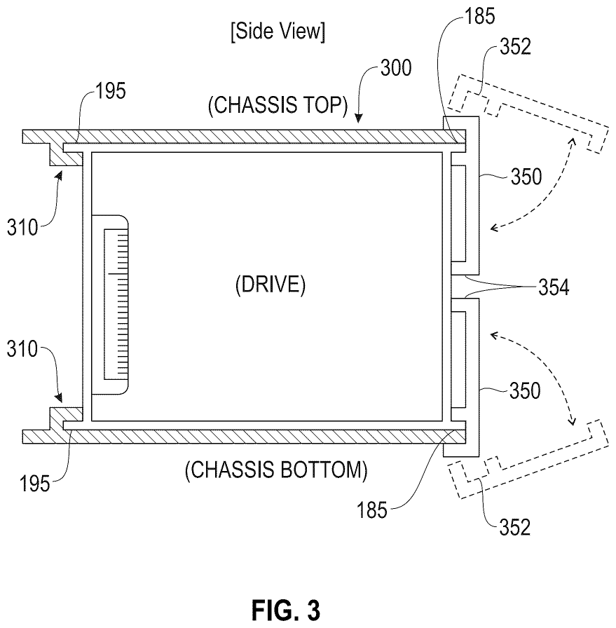

FIG. 3 is a side view of the assembly 100 including the carrier 150 and storage device 110 together mounted or installed within a server chassis 300 according to embodiments. As illustrated in FIG. 3 the carrier 150 is inserted into the chassis where the extensions 195 of the top portion 160 and bottom portion 170 interface with a corresponding interface component 310 of the chassis 300. In some embodiments the interface component is a hem. However, the interface component can be a latch, a pin, a clip, etc. The interface components 310 help the carrier 150 and storage device 110 to anchor to the rear drive section of the server chassis 300.

At the front bracket 180 side of the carrier 150 there are also corresponding extensions 185 from the top portion 160 and bottom portion 170 of the carrier 150. These extensions are provided such that the carrier 150 can be further anchored to the server chassis 300. In some embodiments, a drive latch mechanism 350 is provided to anchor the carrier 150 into the chassis. The drive latch mechanism 350 in one embodiment comprises two separate components that are hingidly connected to a corresponding top and bottom of the server chassis 300. While illustrated as a hinge connection the drive latch mechanism 350 can employ other means for connection such as sliding mechanism, a rotate and slide mechanism, or a snap-in mechanism. However, for purposes of this discussion the hinged approach will be discussed.

When the assembly 100 is inserted into the chassis, each of the drive latch mechanism 350s can then be rotated into position over the corresponding extensions 185 of the top portion 160 and bottom portion 170 of the chassis 300. The drive latch mechanism 350 includes a corresponding hem 352 to engage with the extensions 185. Again, a latch, pin, clip, etc could be used instead of a hem. The bottom part of each of the drive latch mechanism 350 includes a tab 354 that interfaces with the front bracket 180 of the carrier 150 and/or storage device 110. This is provided to keep the drive latch mechanism 350 stable when in the locked position and prevent accidental releasing of the mechanisms. While the present discussion discusses the drive latch mechanism 350 as being two separate mechanisms, it should be recognized that a single mechanism could be used instead. In this approach both of the two hems 352 are placed on a single latch mechanism. This approach has the advantage of having reduced tolerance requirements, but reduces the strength of the connection to the chassis.

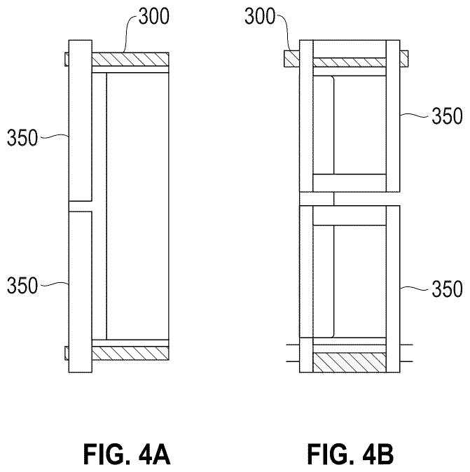

FIG. 4A illustrates a front view of the two-part drive latch mechanism 350 according to one embodiment. In this embodiment the drive latch mechanism 350 only engages the carrier 150 on one side of the carrier 150. FIG. 4B illustrates a front view of the two-part drive latch mechanism 350 according to an alternative embodiment. In this embodiment the drive latch mechanism 350 engages the carrier 150 on two sides of the carrier 150, using a mechanism similar to that in FIG. 4A. However, the connection between the two sides of the drive latch mechanism 350 can be removed in some embodiments making the two-part drive latch mechanism 350 a four part mechanism where each of the corresponding latch mechanism can operate independently of each other.

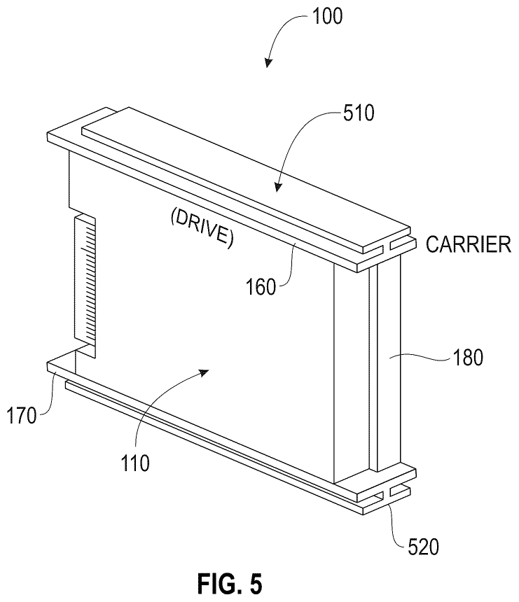

FIG. 5 is a profile view illustrating an alternative embodiment of carrier 150. In this embodiment the top portion 160 and/or the bottom portion 170 further include a T-shaped flange 510, 520 on them. This flange can engage with a slide mechanism (not illustrated) that is built into the server chassis 300. This approach provides the advantage of providing a strong engagement between the carrier 150 and the server chassis 300 across the entire length of the chassis, which in turns provides stronger reinforcement with the storage device 110. However, it can make it difficult to fit certain types of storage devices into the chassis due to the extra overall space consumed by the carrier 150.

Through use of the locking mechanisms of the present disclosure, it becomes possible to fundamentally change the EMC (electro-magnetic compliance) carrier metal that is present in current systems. Instead of mounting EMC carrier metal to each drive, a single piece of perforated metal can be mounted just upstream of the front bracket 180 of the carrier 150 and storage device 110. The baffle can use metal perf material for the EMC control. This provides a lower-impedance solution, as well as greater aesthetic control of the front of the server chassis 300. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structural drive assembly, comprising:
a storage device having a first mounting feature on a first side of the storage device and a second mounting feature on a second side of the storage device;
a carrier comprising:
a top portion configured to attach to the first side of the storage device and interface with the first mounting feature;
a bottom portion configured to attach to the second side of the storage device and interface with the second mounting feature; and
wherein the carrier is fixedly connected to the storage device.

2. The structural drive assembly of claim 1 wherein the carrier further comprises:
a first bracket connecting the top portion and the bottom portion together configured to provide structural rigidity to the carrier.

3. The structural drive assembly of claim 2 wherein the first bracket is narrower than the width of the storage device.

4. The structural drive assembly of claim 2 wherein the carrier further comprises:
a second bracket connecting the top portion and the bottom portion together, wherein the second bracket is at an opposite end of the carrier from the first bracket.

5. The structural drive assembly of claim 1 wherein the top portion and the bottom portion are further configured to anchor with a server chassis.

6. The structural drive assembly of claim 5 wherein the top portion and bottom portion extend beyond a length of the storage device.

7. The structural drive assembly of claim 1 wherein the carrier is connected to the storage device by screws connecting with the first and second mounting features.

8. The structural drive assembly of claim 1 wherein the top portion further includes a T-flange disposed on the top portion.

9. A server system comprising
a server chassis, wherein the server chassis has no structural bracing in a front section of the server chassis;
a structural drive assembly, comprising:
a storage device having a first mounting feature on a first side of the storage device and a second mounting feature on a second side of the storage device;
a carrier comprising:
a top portion configured to attach to the first side of the storage device and interface with the first mounting feature;
a bottom portion configured to attach to the second side of the storage device and interface with the second mounting feature;
wherein the carrier is fixedly connected to the storage device; and
wherein the structural drive assembly is configured to anchor to the server chassis through an interface component of the server chassis and provide structural rigidity to the server chassis.

10. The server system of claim 9 wherein the carrier further comprises:
a first bracket connecting the top portion and the bottom portion together configured to provide structural rigidity to the carrier.

11. The server system of claim 10 wherein the carrier further comprises:
a second bracket connecting the top portion and the bottom portion together, wherein the second bracket is at an opposite end of the carrier from the first bracket.

12. The server system of claim 9 wherein the top portion and bottom portion extend beyond a length of the storage device.

13. The server system of claim 12 wherein a rear portion of the top portion and bottom portion connects with the interface component of the server chassis.

14. The server system of claim 12 wherein the server chassis further comprises:
a drive latch mechanism disposed at a front of the server chassis configured to attach to a front of the carrier to anchor the structural drive assembly to the server chassis.

15. The server system of claim 14 wherein the drive latch mechanism is hingidly connected to the server chassis and configured to rotate over the carrier to anchor the structural drive assembly to the server chassis.

16. The server system of claim 14 wherein the drive latch mechanism comprises two separate drive latch mechanisms configured to anchor the structural drive assembly to the server chassis.

17. The server system of claim 16 wherein a first drive latch mechanism is disposed at a bottom of the sever chassis and a second drive latch mechanism is disposed at a top of the server chasis.

18. The server system of claim 17 wherein the first drive latch mechanism and the second drive latch mechanism are hingidly connected to the server chassis and configure to rotate of the carrier to anchor the structural drive assembly to the server chassis.
